(19) United States
(12) Patent Application Publication
(10) Pub. No.: US 2021/0289619 A1
(43) Pub. Date: Sep. 16, 2021

(54) ELECTRONIC DEVICE AND MOTOR DEVICE

(71) Applicant: DENSO CORPORATION, Kariya-city (JP)

(72) Inventor: Yoshiki KATO, Kariya-city (JP)

(21) Appl. No.: 17/196,103

(22) Filed: Mar. 9, 2021

(30) Foreign Application Priority Data
Mar. 12, 2020 (JP) 2020-043344

(51) Int. Cl. H05K 1/02; H05K 5/06; H02K 11/33

(52) U.S. Cl. CPC H05K 1/0272; H05K 5/065; H02K 2211/03; H05K 2201/10053; H02K 11/33

(57) ABSTRACT

An electronic device includes a wiring board built on or made by (i) an insulating base member having an upper surface and (ii) a wiring arranged at least on the upper surface, including a land arranged on the upper surface to serve as the wiring. Electronic components arranged on the upper surface are sealed by a sealing resin body. The electronic components include a heat-generating component connected to the land and an other component. The wiring includes a conductor pattern arranged on the one surface and extending to the land to which the heat-generating component is connected. The sealing resin body on the upper surface has a hole at an overlap position of the conductor pattern in a plan view, with an opening of the hole facing upwardly.

### CROSS REFERENCE TO RELATED APPLICATION

The present application is based on and claims the benefit of priority of Japanese Patent Application No. 2020-043344, filed on Mar. 12, 2020, the disclosure of which is incorporated herein by reference.

### TECHNICAL FIELD

The present disclosure generally relates to an electronic device and a motor device.

### BACKGROUND INFORMATION

This application discloses an electronic device in which a heat-generating component is connected to a land provided on one surface of a substrate, and the heat-generating component is resin-sealed together with the one surface.

### SUMMARY

It is an object of the present disclosure to provide an electronic device having a simple structure and excellent heat dissipation.

Another disclosed object is to provide a motor device having excellent heat dissipation.

In one embodiment, heat generated by a heat-generating component is transmitted from a land to a conductor pattern. Since a hole is provided in a sealing resin body at a position of the conductor pattern, heat can easily be dissipated from the conductor pattern to an outside of the sealing resin body. As a result, it is possible to provide an electronic device having a simple structure and excellent heat dissipation.

The disclosed aspects in this specification adopt respectively different technical solutions from each other in order to achieve their respective objectives. Reference numerals in parentheses described in claims and this section exemplarily show corresponding relationships with parts of embodiments to be described later and are not intended to limit technical scopes. The objects, features, and advantages disclosed in this specification will become apparent by referring to following detailed descriptions and accompanying drawings.

### BRIEF DESCRIPTION OF THE DRAWINGS

Objects, features, and advantages of the present disclosure will become more apparent from the following detailed description made with reference to the accompanying drawings, in which:

FIG. 1 is an exploded perspective view of a motor device according to a first embodiment;

FIG. 2 is an exploded perspective view seen from a motor side;

FIG. 3 is an exploded perspective view seen from an electronic device side;

FIG. 4 is a plan view with a cover omitted;

FIG. 5 is a cross-sectional view of the electronic device taken along a line V-V of FIG. 4;

FIG. 6 is a cross-sectional view of a modified example of the electronic device; and

FIG. 7 is a cross-sectional view of the electronic device in the motor device according to a second embodiment.

### DETAILED DESCRIPTION

Hereinafter, a plurality of embodiments will be described with reference to the drawings. In the plurality of embodiments, functionally and/or structurally corresponding parts and/or associated parts are provided with the same reference numerals/symbols. For corresponding parts and/or associated parts, additional explanations can be made in the description of the other embodiments.

### First Embodiment

A motor device according to the present embodiment is applied to, for example, a valve timing adjusting device of a vehicle. The valve timing adjusting device is provided in a transmission system of a vehicle which transmits a crank torque from a crank shaft (not shown) of an internal combustion engine to a cam shaft. The cam shaft opens and closes an intake valve of a valve train of the internal combustion engine by transmitting the crank torque. The valve timing adjusting device controls the valve timing of the intake valve.

The valve timing adjusting device includes a phase adjusting mechanism (not shown) and a motor device 10. The basic configuration of the phase adjusting mechanism is the same as that described in, for example, Japanese Patent Laid-Open No. 2015-203392. Regarding the phase adjusting mechanism, the contents described in the above publication is incorporated herein by reference.

<Motor Device>

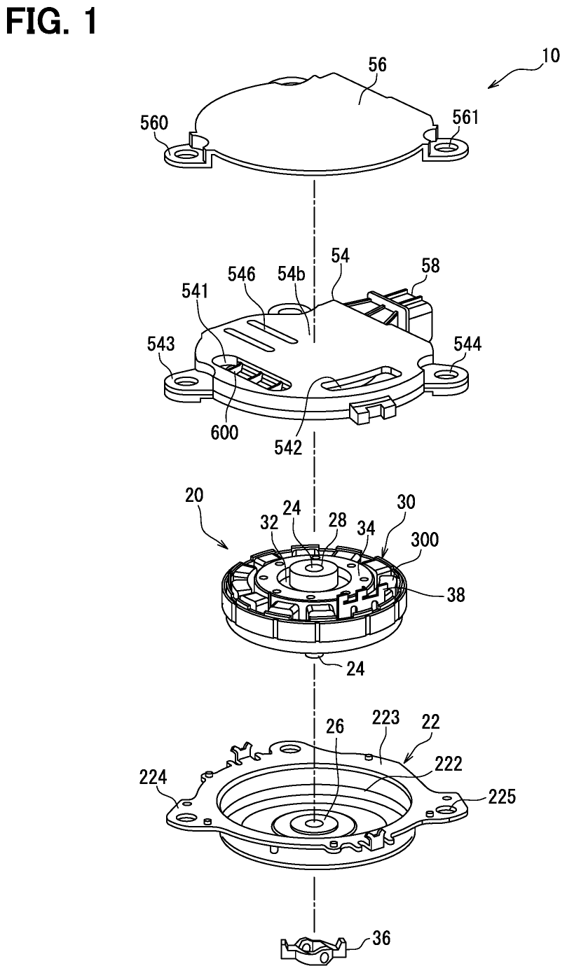

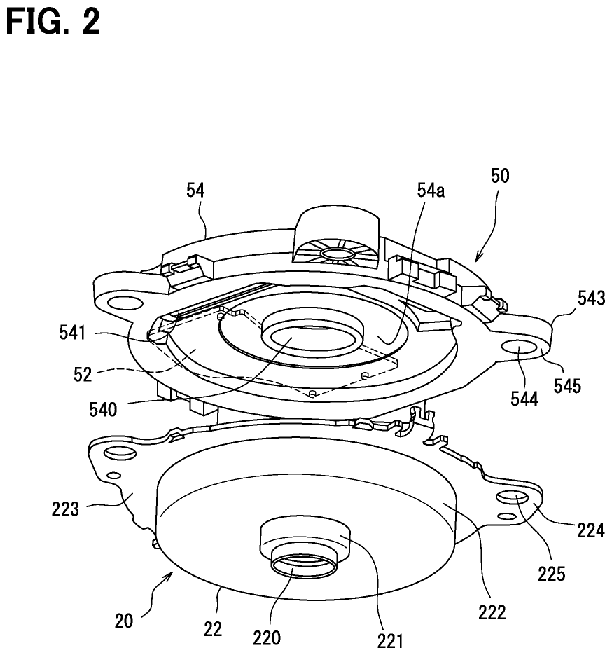

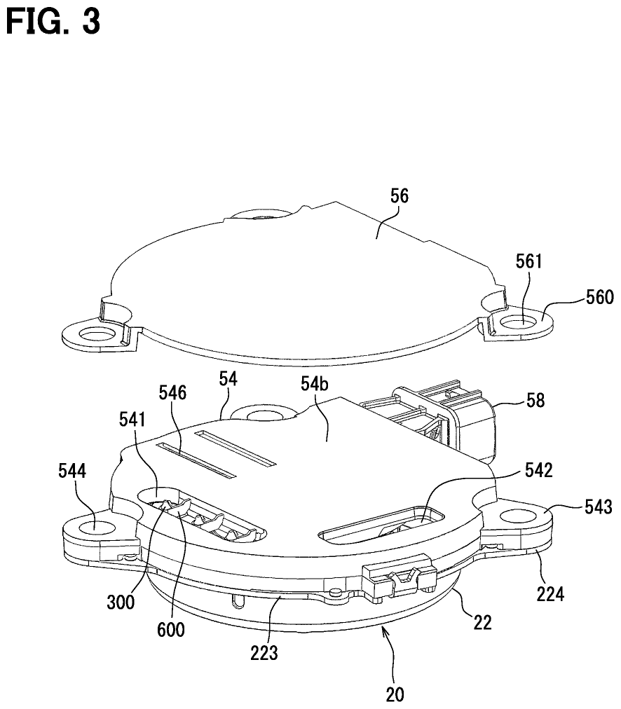

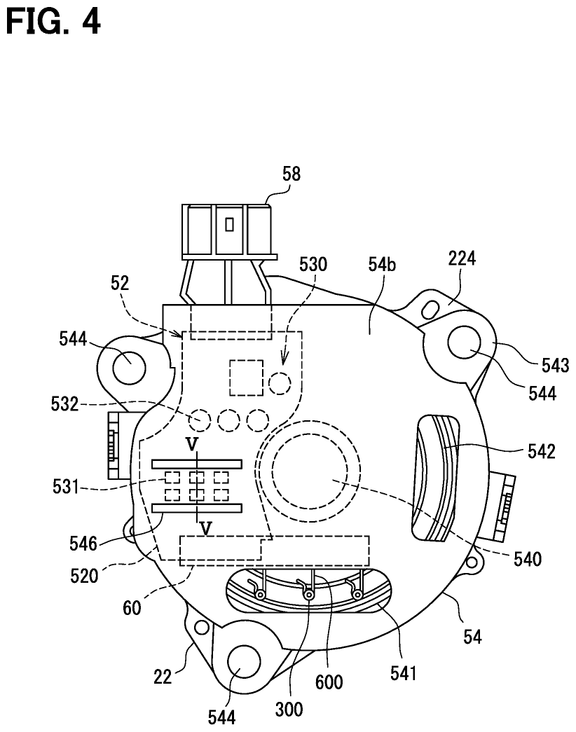

First, a schematic configuration of the motor device according to the present embodiment will be described with reference to FIGS. 1 to 4. FIG. 1 is an exploded perspective view of a motor device. FIG. 2 is an exploded perspective view of the motor device seen from the side opposite to the electronic device, that is, from the motor side. In FIG. 2, for convenience, of the elements of the motor device, only a housing is shown. In FIG. 2, a cover is omitted. FIG. 3 is an exploded perspective view of the motor device seen from the electronic device side. In FIG. 3, only the cover is shown separately. FIG. 4 is a plan view of the motor device with the cover omitted. In FIG. 4, for convenience, of the elements of the motor device, only the housing and the connecting portion of the winding are shown.

As shown in FIGS. 1 to 4, the motor device 10 includes a motor 20 and an electronic device 50. The motor device 10 can also be referred to as a rotating electric machine including an electronic device 50 (EDU). EDU is an abbreviation for Electronic Driver Unit.

The motor 20 is a brushless permanent magnet type synchronous motor. As shown in FIGS. 1 and 2, the motor 20 has a housing 22, a motor shaft 24, bearings 26 and 28, a stator 30, a rotor 32, and a sensor magnet 34.

The housing 22 is made of a metal material such as iron is a substantially cylindrical shape. An upper opening located in the housing 22 is closed by a sealing resin body 54 of the electronic device 50. Other elements 24, 26, 28, 30, 32, and 34 configuring the motor 20 are arranged in an internal housing space of the housing 22. The housing 22 (i.e., the motor device 10) is attached to a fixed node such as a chain case of an internal combustion engine.

As shown in FIG. 2, an opening 220 is formed near the center of the bottom of the housing 22. The motor shaft 24 (see FIG. 1) projects to the outside of the housing 22 through the opening 220 and is connected to the phase adjusting mechanism. A joint 36 (see FIG. 1) for connecting to the phase adjusting mechanism is fixed to one end of the motor shaft 24 on a phase adjusting mechanism side. A seal member (not shown) is interposed at a position between an inner surface of the opening 220 of the housing 22 and the motor shaft 24.

The housing 22 has a small-diameter part 221, a large-diameter part 222, a flange 223, and a plurality of tabs 224. The small-diameter part 221 is provided on the phase adjusting mechanism side in an axial direction of the motor shaft 24 (hereinafter, may simply be referred to as an “axial direction”, or as a “vertical direction” for convenience assuming the sealing resin body 54 is located above the housing 22). The small-diameter part 221 is provided at a position between the opening 220 and the large-diameter part 222. The large-diameter part 222 has a larger diameter than the small-diameter part 221, and is provided on an electronic device 50 side in the axial direction (or an upper direction for convenience). The flange 223 is continuous with the end of the large-diameter part 222 on the electronic device 50 side and extends outward in the radial direction. The plurality of tabs 224 extend radially outward from the flange 223 while being separated from each other in a circumferential direction. The housing 22 of the present embodiment has three tabs 224. A through hole 225 for fixation to, for example, a chain case is formed in each of the plurality of tabs 224.

The bearings 26 and 28 respectively support the motor shaft 24 to be rotatable in a forward and backward directions. In the axial direction, an outer ring of the bearing 26 on the phase adjusting mechanism side is fixed to an inner surface of the small-diameter part 221 of the housing 22, and an inner ring is fixed to the motor shaft 24. The bearing 26 is arranged almost entirely in the small-diameter part 221 in the axial direction. One end of the motor shaft 24 and the bearing 28 are housed in a recess 540 of the sealing resin body 54. Specifically, an outer ring of the bearing 28 is fixed to a side surface of the recess 540, and an inner ring of the bearing 28 is fixed to the motor shaft 24. The bearing 28 holds one end of the motor shaft 24 so as not to allow the one end to contact the sealing resin body 54.

The stator 30 is housed in the large-diameter part 222, and is held by the housing 22. The stator 30 is formed in a substantially cylindrical shape, and has a stator core (not shown) having a plurality of tooth portions, and a winding wire 300 wound around each of the tooth portions. The winding wire 300 corresponding to each of a U phase, a V phase, and a W phase of the motor 20 is connected to a neutral point provided as a terminal 38. The stator 30 generates a rotating magnetic field that acts on permanent magnets of the rotor 32 when a drive current is supplied to the winding wire 300.

The rotor 32 is rotatably housed inside the stator 30. The rotor 32 is formed in an annular plate shape that projects radially outward from the motor shaft 24, and is rotatable in the forward and backward directions in the circumferential direction. The rotor 32 has a rotor core and a permanent magnet (not shown). The rotor core is formed by laminating a plurality of disc-shaped core sheets, for example. The rotor core may be directly fixed to the motor shaft 24 or may be fixed via an engaging member. The permanent magnet is provided integrally with the rotor core and rotates together with the rotor core. The magnetic poles of the plurality of permanent magnets are alternated along the circumferential direction.

The sensor magnet 34 has an annular shape, is fixed to an outer peripheral edge of a surface of the rotor 32 on the electronic device 50 side, and rotates together with the rotor 32. The sensor magnet 34 is provided to detect a rotational position of the rotor 32. The sensor magnet 34 has N poles and S poles alternately provided at predetermined angles.

The electronic device 50 is a device including a circuit for driving the motor 20. The electronic device 50 corresponds to the drive device of the motor 20. The electronic device 50 is positioned and fixed to the motor 20. The electronic device 50 includes a circuit board 52, the sealing resin body 54, and a cover 56. The circuit board 52 has a wiring board (or insulating base member) 520 and a plurality of electronic components 530 mounted on the wiring board 520. The wiring board 520 may be referred to as a printed circuit board. A circuit is formed by the wiring of the wiring board 520 and the electronic component 530. The plurality of electronic components 530 include a plurality of switches, Hall elements, drive ICs, capacitors, coils, etc. for driving the motor 20.

The plurality of switches form an inverter. The inverter is a DC-AC conversion circuit that converts a DC voltage into a three-phase AC voltage and outputs it to the motor 20. The Hall element is mounted on a surface of the wiring board 520 facing the motor 20. The Hall element detects the rotational position of the rotor 32 and outputs a detection signal to the drive IC. The Hall element is provided to face the sensor magnet 34. The electronic device 50 has, for example, three Hall elements provided at intervals of a predetermined rotation angle along the circumferential direction.

The drive IC detects the rotational position of the rotor 32 based on the detection signal of the Hall element. The drive IC acquires a drive instruction for the motor 20 from an ECU (not shown) and drives each switch, that is, performs ON drive and OFF drive of each switch based on the drive instruction and the rotational position. The drive IC may sometimes be called a driver. “ECU” is an abbreviation of “Electronic Control Unit.” The capacitor includes a smoothing capacitor and a filter capacitor that removes power supply noise together with the coil.

The circuit board 52 has an external connector 58 and an internal connector 60 for connection with the outside of the electronic device 50. The external connector 58 electrically relays the above-described ECU and the drive IC, for example. Further, power is supplied to the circuit board 52 via the external connector 58. The internal connector 60 electrically relays the three-phase output line of the inverter and the winding wire 300 of the motor 20.

The sealing resin body 54 seals at least a part of the plurality of electronic components 530 provided on the circuit board 52 together with the wiring board 520. The sealing resin body 54 seals at least the surface of the wiring board 520 on a cover 56 side, that is, a surface opposite to a motor 20 side. The electronic device 50 is a resin-sealed electronic device.

The sealing resin body 54 of the present embodiment also seals the upper surface of the wiring board 520. The sealing resin body 54 seals all of the electronic components 530 mounted on the wiring board 520. The sealing resin body 54 seals the circuit board 52 almost entirely in some embodiments. The electronic device 50 is a full-mold type electronic device. The sealing resin body 54 has a substantially disc shape. The sealing resin body 54 seals a part of the external connector 58, specifically, a part including a connection portion with the wiring board 520. A portion of the external connector 58 that is connected to an external device is exposed to the outside of the sealing resin body 54.

The sealing resin body 54 has the recess 540. The recess 540 is a blind hole that opens facing down from a lower surface 54a of the sealing resin body 54. As described above, the recess 540 accommodates one end of the motor shaft 24 and the bearing 28. The circuit board 52 is provided so as not to overlap the recess 540 in a plan view along the axial direction. The circuit board 52 is arranged to avoid the recess 540.

The sealing resin body 54 has through holes 541 and 542. The through holes 541 and 542 penetrate the sealing resin body 54 in the axial direction. The through holes 541 and 542 open upwardly from the upper surface 54a on downwardly from a lower surface 54bA terminal 600 of the internal connector 60 projects upwardly into the through hole 541. For example, a connection portion between the terminal 600 and the winding wire 300 is arranged in the through hole 541. The above-mentioned terminal 38 is arranged in the through hole 542.

The sealing resin body 54 of the present embodiment closes the opening of the housing 22 as described above. The sealing resin body 54 functions as an upper housing of the motor 20, and joins at a perimeter with the (lower) housing 22. A sealing member (not shown) is optionally interposed at a position between the sealing resin body 54 and the flange 223 of the housing 22. The sealing member is interposed, for example, at an outer peripheral edge portion thereof.

The sealing resin body 54 has the same number of tabs 543 as the tabs 224. A through hole 544 is formed in each of the tabs 543. The tab 543 and the through hole 544 overlap (i.e., are aligned with) the tab 224 and the through hole 225 of the housing 22 in a state where the motor 20 and the electronic device 50 are positioned relative to each other for assembly. The through hole 544 is provided as an inner wall of a collar 545, when, for example, the collar 545 is inserted into the sealing resin body 54, which is a cylindrical member made of metal.

The sealing resin body 54 further has a through hole 546 (in FIGS. 4, 5, and 6), or a blind hole 547 (in FIG. 7). In FIG. 4, two through holes 546 are each slot-shaped, and are located at opposing sides of the heat-generating components 531. The heat dissipation structure of the heat-generating components including the hole 546 is described later.

The cover 56 is made of a metallic material such as iron and is provided in a substantially disc shape. The cover 56 is arranged on a surface 54b side of the sealing resin body 54. The cover 56 has the same number of tabs 560 as the tabs 224. A through hole 561 is formed in each of the tabs 560. The tab 560 and the through hole 561 overlap the tab 224 and the through hole 225 of the housing 22 via the tab 543 and the through hole 544 of the sealing resin body 54. A fastening member (not shown) such as a bolt is inserted through the through holes 561, 544, 225, and the motor device 10 is fixed to the chain case.

<Heat Dissipation Structure>

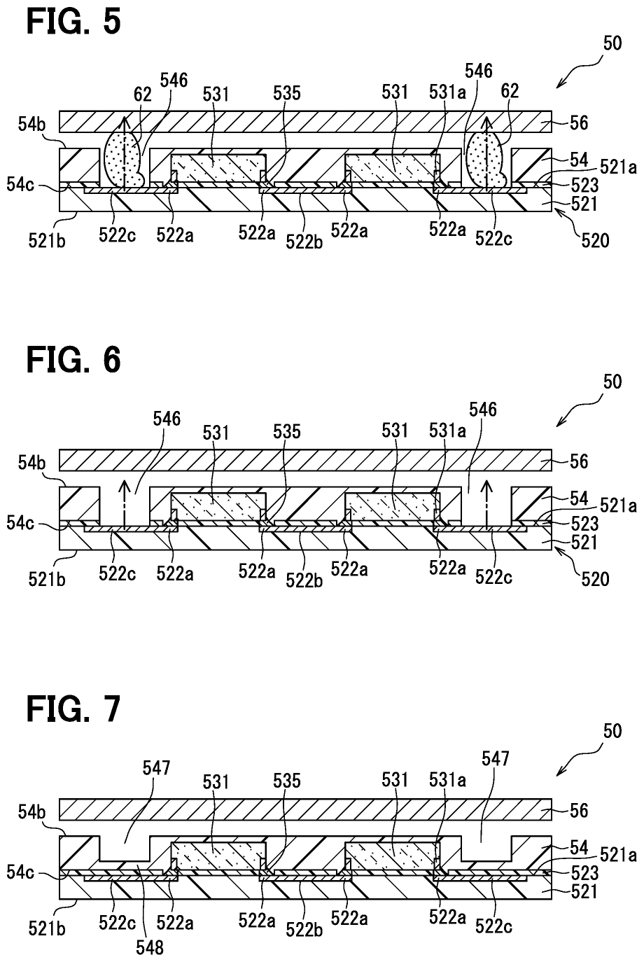

Next, the heat dissipation structure of the heat-generating component is described with reference to FIGS. 4 and 5. FIG. 5 is a cross-sectional view of the electronic device 50 taken along a line V-V of FIG. 4.

The circuit board 52 is arranged such that the substrate thickness direction of the wiring board 520 (i.e., the insulating base member 521) is vertical. In other words, the circuit board 52 is oriented substantially horizontally. The wiring board 520 has an insulating base member 521 made of resin or the like and a wiring 522 arranged on the insulating base member 521. The insulating base member 521 has, as plate surfaces, an upper surface 521a that is a surface facing the cover 56, and a lower surface 521b. The lower surface 521b is a surface on the motor 20 side.

The wiring 522 is formed by patterning a metal foil made of copper, for example. The wiring 522 is arranged at least on the upper surface 521a. The wiring 522 is disposed on the upper surface 521a and includes a land (or pad) 522a which is an electrode portion to which the electronic component 530 is connected. The land 522a is exposed upwardly from areas not covered by a solder resist 523 provided on the upper surface 521a. The wiring 522 of the present embodiment is arranged in multiple layers with respect to the insulating base member 521. For example, it is also arranged on the back surface 521b. In FIG. 5, for convenience, only the wiring 522 arranged on the one surface 521a is shown. Similarly, the electronic component 530 disposed on the back surface 521b and the sealing resin body 54 that covers the back surface 521b are omitted in the drawing.

On the one surface 521a, as the plurality of electronic components 530, a heat-generating component 531 and other component 532 that is an electronic component that generates less heat than the heat-generating component 531 are arranged. The heat-generating component 531 is a switch (for example, MOSFET) that constitutes an inverter. The circuit board 52 has six heat-generating components 531. The two heat-generating components 531 (i.e., switches) that form the inverter are arranged along a line. The six heat-generating components 531 are arranged in three rows. The heat-generating component 531 has a terminal 531a for external connection. The terminal 531a is joined to the corresponding land 522a via a solder 535.

The wiring 522 is disposed on the one surface 521a and has conductor patterns 522b and 522c which lead to the land 522a. The conductor pattern 522b electrically connects a source of the heat-generating component 531 forming the upper arm and a drain of the heat-generating component 531 forming the lower arm. The lands 522a are provided on both ends of the conductor pattern 522b. The conductor pattern 522b of the present embodiment is covered with the solder resist 523.

One of the conductor patterns 522c is electrically connected to a drain of the heat-generating component 531 forming the upper arm. The other one of the conductor patterns 522c is electrically connected to a source of the heat-generating component 531 forming the lower arm. The conductor pattern 522c extends from the corresponding land 522a in a direction away from the heat-generating component 531. The conductor pattern 522c extends along a direction in which the two heat-generating components 531 forming the upper and lower arm circuits are arranged.

The sealing resin body 54 seals all of the plurality of electronic components 530 arranged on the one surface 521a together with the wiring board 520. The sealing resin body 54 seals the heat-generating component 531 and the other component 532. As described above, the sealing resin body 54 arranged on the one surface 521a has the hole 546. The hole 546 is opened in the surface 54b on the cover 56 side, and is provided at a position overlapping the conductor pattern 522c in a plan view along the substrate thickness direction (that is, the axial direction or vertical direction). One (slot-shaped) hole 546 is provided corresponding to each of the conductor patterns 522c.

In the present embodiment, the hole 546 is a through hole having the wiring board 520 located below the hole 546. The hole 546 also has an opening opened in a surface 54c on a wiring board 520 side of the sealing resin body 54 arranged on the one surface 521a. The hole 546 is a long hole or an oval-like hole, which has a short diameter aligned with a line of arrangement of the two heat-generating components 531 (which may be a lateral direction of the hole 546), and a long diameter perpendicular to both of the line of arrangement of the two heat-generating components 531 and the substrate thickness direction. The sealing resin body 54 has two holes 546. One of the holes 546 is overlapped with each of the conductor patterns 522c connected to the drain of the heat-generating component 531 serving as the upper arm. The other one of the holes 546 is overlapped with each of the conductor patterns 522c connected to the source of the heat-generating component 531 serving as the lower arm.

A portion of the conductor pattern 522c that overlaps the hole 546 is exposed from the solder resist 523, like the land 522a. At a position between the exposed portion of the conductor pattern 522c and the land 522a, there is a covered portion of the conductor pattern 522c covered with the solder resist 523. A heat conducting member 62 having flexibility/elasticity is arranged in the hole 546 of the sealing resin body 54. The heat conducting member 62 is in contact with the exposed portion of the conductor pattern 522c forming a surface of the wiring board 520 and an inner surface of the cover 56, respectively. The heat conducting member 62 is, for example, a heat radiating gel or heat radiating grease. The heat conducting member 62 has a higher heat conductivity than air.

In other words, looking at FIG. 4, a first slot 546 is parallel with a second slot 546, and six heat-generating components (driver switches of a driver circuit) are located between the slots. For example, a common/standard driver circuit for a three phase inverter includes six switches or arms: an upper U-phase switch associated with a lower U-phase switch connected in a first series, an upper V-phase switch associated with a lower V-phase switch and connected in a second series, and an upper W-phase switch associated with a lower W-phase switch and connected in a third series. A first end of the upper U-phase switch is connected to a power supply. A second end of the upper U-phase switch is connected to a U-phase winding of the motor and is connected to a first end of the lower U-phase switch. A second end of the lower U-phase switch is connected to a ground.

The V-phase switches similarly serve a V-phase winding of the motor, and the W-phase switches similarly serve a W-phase winding of the motor. In one embodiment, the first ends of the phase switches are drains, and the second ends are sources for an n-channel enhancement mode MOSFET.

The first slot 546 may be located over the first ends of the three upper switches, and the second slot 546 may be located over the second ends of the three lower switches.

For example, looking at FIG. 5, the leftward heat generating component 531 is the upper U-phase switch, and the rightward heat generating component 531 is the lower U-phase switch.

### Summary of the First Embodiment, FIGS. 5, 6

In the electronic device 50 of the present embodiment, heat generated by the heat-generating component 531 is transmitted to the conductor pattern 522c via the land 522a. For example, heat may transfer along metal following an electrical conduction path: from the terminal 531a of the heat generation component 531, to solder 535, to a land portion 522a of conductor pattern 522c; to a central portion of the conductor pattern 522c located under the hole or slot 546. The sealing resin body 54 has the hole 546 at a position overlapping the conductor pattern 522c. As a result, heat can be more easily released/dissipated from the conductor pattern 522c to the outside of the sealing resin body 54, as compared with a configuration having no hole 546. By the patterning of the wiring 522 and the molding of the sealing resin body 54, the above effects are achievable. Therefore, it is possible to provide the electronic device 50 having a simple structure and excellent heat dissipation. Since it is not necessary to dispose a heat dissipation plate (e.g., a heat sink) on the lower surface 521b in order to dissipate heat of the heat-generating component 531 arranged on the one surface 521a, the size/volume of the electronic device 50 is reducible.

In the present embodiment, the hole 546 is a through hole having the wiring board 520 as a bottom. The sealing resin body 54 does not exist at least above a part of the conductor pattern 522c. Thereby, heat dissipativity is further improvable. A heat conducting member 62 may directly transfer heat from the conductor pattern 522 to the cover 56, as shown in FIG. 5.

In terms of the wiring 522, only the land 522a may be exposed from the solder resist 523. That is, the solder resist 523 may cover a portion of the conductor pattern 522c that overlaps the hole 546, as shown in FIG. 7. In the present embodiment of FIG. 5, at least a portion of the conductor pattern 522c that overlaps the hole 546 is exposed from the solder resist 523. As a result, heat can be released/dissipated from the conductor pattern 522c to the outside of the sealing resin body 54 without passing through the solder resist 523. Therefore, heat dissipation is further improvable.

As in a modified example shown in FIG. 6, heat may be released from the conductor pattern 522c to the air in the hole 546. FIG. 6 is a cross-sectional view corresponding to FIG. 5. According to such a configuration, a size of the heat dissipation area can be increased as compared with a configuration in which the sealing resin body 54 is present at the position of (e.g., in an inside of) the hole 546. Therefore, heat dissipation is further improved. In the present embodiment of FIG. 5, the heat conducting member 62 having flexibility (for example, heat dissipation gel) is arranged in the hole 546. The heat conducting member 62 is in contact with the conducting pattern 522c of the wiring board 520. Therefore, it is possible to improve the heat dissipation as compared with the configuration shown in the modified example. Dashed-dotted line arrows shown in FIGS. 5 and 6 indicate heat transmission paths.

In particular, in the present embodiment of FIG. 5, the heat conducting member 62 is in contact not only with the wiring board 520 but also with the cover 56 made of metal. Heat generated by the heat-generating component 531 is transmitted to the cover 56 from the conductor pattern 522c via the heat conducting member 62. Thus, heat dissipation is further improvable. The cover 56 corresponds to a metal member.

For example, in the motor device 10, the heat radiation structure described above may radiate/dissipate heat toward the motor 20 side. That is, the heat-generating component 531 may be disposed on the surface on the motor 20 side of the wiring board 520, and the hole 546 may be provided in the sealing resin body 54 that covers the heat-generating component 531. In the present embodiment, in the wiring board 520, the heat-generating component 531 is arranged on the one surface 521a, which is opposite to (i.e., faces away from) the motor 20, and the hole 546 is provided in the sealing resin body 54 on the one surface 521a. As a result, heat generated by the heat-generating component 531 can be dissipated to a side opposite to the motor 20 that generates heat when energized. As a result, it is possible to provide the motor device 10 having excellent heat dissipation.

### Second Embodiment, FIG. 7

The second embodiment is a modification of a preceding embodiment as a basic configuration and may incorporate description of the precedent embodiment. In the preceding embodiment, the hole is a through hole. Instead, a non-penetrating hole may also be used.

FIG. 7 is a cross-sectional view showing the electronic device 50 of the present embodiment. FIG. 7 corresponds to FIG. 5, with the exceptions of: the shape of the sealing resin body 54, the an absence of the heat conducting member 62, and the shape of the solder resist 523. The sealing resin body 54 has a hole 547 that does not penetrate thereof. The hole 547 is a blind hole that has an (upward facing) opening opened in the surface 54b on the cover 56 side, and is provided at a position overlapping the conductor pattern 522c in a plan view along the substrate thickness direction. The hole 547 does not have an opening opened in the surface 54c on the wiring board 520 side of the sealing resin body 54. In other words, the hole 547 in FIG. 7 is a blind hole that opens upwardly.

The sealing resin body 54 has a thin portion 548 directly below the hole 547. In the sealing resin body 54, the thickness of the thin portion 548 is smaller than the thickness of the surrounding portion of the hole 547. The thin portion 548 of the present embodiment is the thinnest portion of the sealing resin body 54 arranged on the one surface 521a.

Of the wiring 522, only the land 522a is exposed from the solder resist 523. A portion of the conductor pattern 522c that overlaps the hole 547 is also covered with the solder resist 523. The configuration other than the above is the same as the configuration described in the preceding embodiment.

### Summary of the Second Embodiment, FIG. 7

In the electronic device 50 of the second embodiment, the hole 547 is formed in the sealing resin body 54 at a portion overlapping the conductor pattern 522c. As a result, the heat generated by the heat-generating component 531 can be easily released to the outside of the sealing resin body 54 via the land 522a and the conductor pattern 522c. Therefore, it is possible to provide the electronic device 50 having a simple structure and excellent heat dissipation.

The structure having the hole 547 can be combined with various structures shown in the preceding embodiments. For example, the heat conducting member 62 may be arranged in the hole 547. The heat conducting member 62 is arranged to contact the bottom surface of the hole 547. As a result, it is possible to improve heat dissipation compared to a configuration in which the heat conducting member 62 is not arranged. Further, the heat conducting member 62 may be brought into contact with the cover 56. According to such structure, heat can be released from the conductor pattern 522c to the cover 56 via the heat conducting member 62. Thus, heat dissipation is further improvable.

Also, for example, in the motor device 10, the heat radiation structure described above may transfer heat toward the motor 20 side. That is, the heat-generating component 531 may be arranged on the surface on the motor 20 side, and the hole 547 may be provided in the sealing resin body 54 that covers the heat-generating component 531. In the second embodiment, in the wiring board 520, the heat-generating component 531 is arranged on the one surface 521a opposite to the motor 20, and the hole 547 is provided in the sealing resin body 54 on the one surface 521a. As a result, heat generated by the heat-generating component 531 can be dissipated to a side opposite to the motor 20 that generates heat when energized. As a result, it is possible to provide the motor device 10 having excellent heat dissipation.

### Other Embodiments

The present disclosure in the specification, drawings and the like is not limited to the exemplified embodiments. The present disclosure encompasses the exemplified embodiments and modifications based on the embodiments by those skilled in the art. For example, the present disclosure is not limited to the combinations of parts and/or elements shown in those embodiments. The present disclosure may be implemented in various combinations. The present disclosure may have additional parts that are addable to the embodiment. The present disclosure encompasses omissions of parts and/or elements from those embodiments. The present disclosure encompasses replacement or combination of components, elements between one embodiment and the other(s). The disclosed technical scope is not limited to the description of the embodiments. It is to be understood that some of the technical scopes disclosed hereby are shown by the description of the claims, and further include meanings equivalent to the description of the claims and all modifications within the scope.

The present disclosure in the specification, drawings and the like is not limited by the description of the claims. The disclosures in the specification, the drawings, and the like encompass the technical ideas described in the claims, and further extend to a wider variety of technical ideas than those in the claims. Therefore, various technical ideas can be extracted from the disclosure of the specification, the drawings and the like without being limited to the description of the claims.

The spatially relative terms “below” and “above” are used herein to facilitate a description of the relationship of one element or feature to another element or feature, as shown in the drawing. Spatially relative terms intend to encompass different orientations of the device during use or operation in addition to the orientation depicted in the drawing. For example, when the device in the drawing is flipped over, elements described as “below” other elements or features are placed/position “above” the other elements or features. Thus, the term “below” can encompass both of above and below. The device may be oriented in other directions (rotated 90 degrees or otherwise) and the spatially relative descriptors used herein are interpreted accordingly in such cases.

Although an example of a switch forming an inverter is shown as the heat-generating component 531, the present disclosure is not limited thereto. Of the plurality of electronic components 530 arranged on the same surface, the component that generates a larger amount of heat than the other components 532 may be designated as a heat-generating component. The switch (i.e., the heat-generating component 531) is not limited to the MOSFET. For example, it may be an IGBT.

The electronic device 50 is not limited to an application to the motor device 10. Although an example in which the electronic device 50 includes the cover 56 is shown, the present disclosure is not limited thereto. The cover 56 may be omitted from the structure described above.

Although an example in which the solder resist 523 is provided at a position between the land 522a and the exposed portion of the conductor pattern 522c has been shown, the present disclosure is not limited thereto. It is also possible to eliminate the solder resist 523 between the land 522a and the conductor pattern 522c. Providing the solder resist 523 in between can suppress the wetting and spreading of the solder 535 to the outside from the land 522a.

Although an example in which the holes 546 and 547 are provided at the position overlapping the conductor pattern 522c in the sealing resin body 54 has been shown, the present disclosure is not limited thereto. The holes 546 and 547 may be provided at positions overlapping the conductor pattern 522b.

The sealing resin body 54 may be provided only on the one surface 521a among the two surfaces (i.e., among the one surface 521a and the back surface 521b). The sealing resin body 54 may be provided on both of the one surface 521a and the back surface 521b. That is, the sealing resin body 54 may be provided to cover substantial entirety of the wiring board 520. In the structure in which both surfaces of the wiring board 520 are resin-sealed, the heat dissipation structure described above may be applied to both surfaces (i.e., to one surface 521a and to back surface 521b).

The terms “vertical”, “upper”, and “lower” are generally based on the orientation of FIGS. 5, 6, and 7, from the view of the reader.

When describing driver switches of the driver circuit, the term “upper” indicates that the driver switch is attached to the power source, and the term “lower” indicates attached to the ground. This terminology is conventional in the art.

What is claimed is:

1. An electronic device comprising:
a wiring board including: (i) an insulating base member having an upper surface and a lower surface opposite to the upper surface in a vertical direction and (ii) a wiring arranged at least on the upper surface, including a land arranged on the one surface to serve as the wiring;
electronic components arranged on the upper surface and electrically connected to the wiring; and
a sealing resin body sealing upper and side surfaces of the electronic components, wherein
the electronic components include (a) a heat-generating component connected to the land, and (b) an other component having a smaller heat generation amount than the heat-generating component,
the wiring has a first conductor pattern arranged on the one surface and connected to the land,
the sealing resin body has a hole positioned to overlap the conductor pattern in a plan view, and
an opening of the hole faces upwardly.

2. The electronic device of claim 1, wherein
the hole is a through hole,
the wiring board serves as a bottom for the hole, and
the hole penetrates the sealing resin body in a downward direction.

3. The electronic device of claim 2 further comprising:
solder resist located on at least part of an upper surface of the first conductor pattern, wherein
the heat-generating electronic component is soldered to the wiring board, and
in the first conductor pattern, at least a part of a portion overlapping the hole is exposed from the solder resist.

4. The electronic device of claim 1, wherein
the hole is a blind hole having a predetermined depth.

5. The electronic device of claim 1 further comprising:
a heat conducting member that is flexible and that is disposed in the hole and is in contact with the bottom of the hole.

6. The electronic device of claim 5 further comprising:
a metal cover arranged to cover the sealing resin body, wherein
the heat conducting member is in contact with a bottom surface and the metal cover.

7. A motor device comprising:
a motor; and
an electronic device fixed to the motor, wherein
the electronic device includes:
a wiring board including: (i) an insulating base member having an upper surface facing away from the motor and (ii) a wiring arranged at least on the upper surface, including a land arranged on the upper surface to serve as part of the wiring;
electronic components respectively arranged on the one surface and electrically connected to the wiring; and
a sealing resin body sealing the electronic components together with the wiring board,
wherein the electronic components include (a) a heat-generating component connected to the land on the upper surface, and (b) an other component having a smaller heat generation amount than the heat-generating component,
the wiring includes a first conductor pattern that is: (i) arranged on the upper surface and (ii) extends to the land to which the heat-generating component is connected, and
the sealing resin body has a hole positioned to overlap the conductor pattern in a plan view, such that an opening of the hole faces upwardly.

8. An electronic device comprising:
a wiring board;
heat generating components located on the wiring board and including six switches formed in a two by three array, wherein the six switches include a first switch, a second switch, a third switch, a fourth switch, a fifth switch, and a sixth switch; and
a sealing resin body sealing the heat generating components to the wiring board, and including a first slot and a second slot,
wherein the first slot is located outside of a first side of the array, such that the first slot is adjacent to the first switch, the second switch, and the third switch, and
the second slot is parallel with the first slot and is located outside of an opposite side of the array, such that the second slot is adjacent to the fourth switch, the fifth switch, and the sixth switch.

9. The electronic device of claim 8, wherein there is no slot located inside of the array.

10. The electronic device of claim 8, wherein the wiring board includes
(i) a first conductor pattern including a first land located at a right side of the first conductor pattern,
(ii) a second conductor pattern including a second land located at a left side of the second conductor pattern, and a third land located at a right side of the second conductor pattern,
(iii) a third conductor pattern including a fourth land located at a left side of the third conductor pattern,
wherein the first land is located directly under and electrically connected to a left terminal of the second switch,
wherein the second land is located directly under and electrically connected to a right terminal of the second switch,
wherein the third land is located directly under and connected to a left terminal of the fifth switch, and
wherein the fourth land is located directly under and connected to a right terminal of the fifth switch.

11. The electronic device of claim 10, wherein
the first slot reaches and exposes an upper portion of the first conductor pattern, and
the second slot reaches and exposes an upper portion of the third conductor pattern.

12. The electronic device of claim 11, wherein
a first heat conducting member contacts the upper portion of the first conductor pattern and contacts a lower surface of a cover, and
a second heat conducting member contacts the upper surface of the third conductor pattern and contacts the lower surface of the cover.

13. The electronic device of claim 11, wherein
the first conductor pattern is covered by, from left to right, a first portion of solder resist, the first slot, a second portion of solder resist, and a first solder,
a third portion of solder resist is located between the first conductor pattern and the second conductor pattern,
the second conductor pattern is covered by, from left to right, a second solder, a fourth portion of solder resist, and a third solder,
a fifth portion of solder resist is located between the second conductor pattern and the third conductor pattern, and
the third conductor pattern is covered by, from left to right, a fourth solder, a sixth portion of solder resist, the second slot, and a seventh portion of solder resist.

14. The electronic device of claim 8, wherein
the six switches form a driver circuit for a three phase motor,
the second switch is an upper V-phase switch,
the fifth switch is a lower V-phase switch,
the first conductor pattern electrically connects a drain of the second switch to a power supply voltage,
the second conductor pattern electrically connects: a source of the second switch, a drain of the fifth switch, and a V-phase winding of the motor, and
the third conductor pattern electrically connects a source of the fifth switch to a ground.
